(19) United States
(12) Patent Application Publication
(10) Pub. No.: US 2016/0035667 A1
(43) Pub. Date: Feb. 4, 2016

(54) Methods of Packaging Semiconductor Devices and Packaged Semiconductor Devices

(71) Applicant: Taiwan Semiconductor Manufacturing Company, Ltd., Hsin-Chu (TW)

(72) Inventors: Chih-Fan Huang, Kaoshung City (TW); Chih-Wei Lin, Zhubei City (TW); Wei-Hung Lin, Xinfeng Township (TW); Ming-Da Cheng, Jhubei City (TW); Chung-Shi Liu, Hsin-Chu (TW)

(21) Appl. No.: 14/447,387

(22) Filed: Jul. 30, 2014

(51) Int. Cl. H01L 23/498; H01L 21/3105; H01L 23/00; H01L 21/48; H01L 21/78; H01L 21/56; H01L 21/768

(52) U.S. Cl. CPC H01L 23/49861; H01L 21/565; H01L 21/31051; H01L 21/768; H01L 21/4853; H01L 21/78; H01L 21/4803; H01L 21/561; H01L 23/49811; H01L 23/49838; H01L 23/564

(57) ABSTRACT

Methods of packaging semiconductor devices and packaged semiconductor devices are disclosed. In some embodiments, a method of packaging a semiconductor device includes providing a protective film, coupling dies to the protective film, and disposing a molding material around the dies. The protective film includes a substantially opaque material at predetermined wavelengths of light.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon.

Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area. These smaller electronic components such as integrated circuit dies also require smaller packages that utilize less area than packages of the past, in some applications. Chip scale packaging (CSP) is one type of smaller packaging technique.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 10 are cross-sectional views illustrating a method of packaging a semiconductor device at various stages in accordance with some embodiments of the present disclosure, wherein an opaque protective film is included on the package.

FIG. 11 illustrates a cross-sectional view of a packaged semiconductor device in accordance with some embodiments.

FIG. 12 is a graph showing penetration rates in percentages (%) of various wavelengths of light for the protective film in accordance with some embodiments.

FIG. 13 is a flow chart of a method of packaging a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide novel methods of packaging semiconductor devices and structures thereof, wherein a protective film is applied to a carrier before an integrated circuit die is packaged. The protective film is opaque and adhesive. The protective film remains on the back side of the packaged semiconductor device and provides protection from moisture intrusion and de-lamination, to be described further herein.

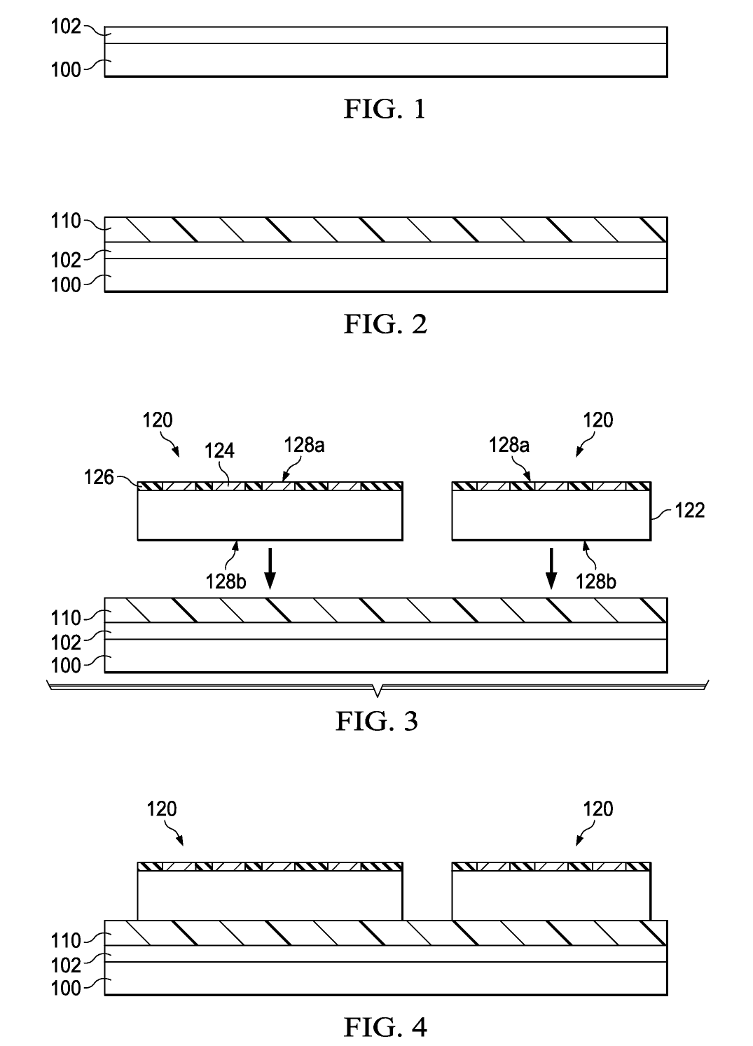

FIGS. 1 through 10 are cross-sectional views illustrating a method of packaging a semiconductor device at various stages in accordance with some embodiments of the present disclosure, wherein an opaque protective film is included on the package. Referring first to FIG. 1, to package the semiconductor device, a carrier 100 is provided. The carrier 100 may comprise glass, silicon oxide, aluminum oxide, or a semiconductor wafer, as examples. The carrier 100 may also comprise other materials. The carrier 100 comprises a thickness of about 500 μm to about 1,000 μm, for example. The carrier may be circular, square, or rectangular in a top view, as examples. Alternatively, the carrier 100 may comprise other dimensions or shapes.

The carrier 100 has a film 102 formed thereon in some embodiments. The film 102 comprises a light to heat conversion (LTHC) material or other materials, for example. The LTHC film 102 comprises a thickness of about 1 μm to about 10 μm, for example. Alternatively, the film may comprise other dimensions. In some embodiments, the film 102 is not included.

Next, in accordance with some embodiments of the present disclosure, a protective film 110 is formed on the carrier 100 over the film 102, as shown in FIG. 2. The protective film 110 comprises an opaque material in some embodiments that is opaque at predetermined wavelengths of light, for example. The protective film 110 comprises a thickness of about 25 μm in some embodiments. The protective film 110 may comprise a thickness of about 10 μm to about 50 μm in other embodiments, as another example. The thickness of the protective film 110 is sufficient to provide a desired amount of opaqueness and to achieve a predetermined desired amount of protection qualities for the protective film 110, for example. Alternatively, the protective film 110 may comprise other dimensions.

The protective film 110 may be formed using a spin-on process, a chemical vapor deposition (CVD) process, a physical vapor deposition (PVD) process, a sputtering process, a lithography process, a taping process, a lamination process, other types of deposition processes, other methods, or a combination thereof, as examples.

In some embodiments, the protective film 110 comprises a solid epoxy resin or an epoxy having a concentration range of about 30% to about 50%. In other embodiments, the protective film 110 comprises phenol resin or phenol having a concentration range of about 10% to about 30%. The protective film 110 may also comprise fused silica or silica having a concentration range of about 2% to about 20%. The protective film 110 may comprise SiO₂, as an example. In some embodiments, the protective film 110 may comprise an organic dye having a concentration range of about 1% to about 10%. The protective film 110 comprises a material that has an adhesive quality in some embodiments, for example. Alternatively, the protective film 110 may comprise other materials and properties.

The protective film 110 comprises an opaque material having a light transmittance of less than or below about 10% in a visible spectrum, e.g., at wavelengths of light between about 380 nm to about 780 nm, in some embodiments. The infrared (IR) penetration of the protective film 110 comprises a light transmittance of about 80% or greater using a CO₂ laser at a wavelength of about 1,060 nm, for example, in some embodiments. Alternatively, the protective film 110 may comprise other penetration percentage rates and ranges, in other embodiments.

Referring next to FIG. 3, a plurality of integrated circuit dies 120 are provided and are bonded to the protective film 110. The integrated circuit dies 120 are also referred to herein, e.g., in some of the claims, as dies 120. The integrated circuit dies 120 comprise semiconductor devices that will be packaged in accordance with some embodiments of the present disclosure. The integrated circuit dies 120 may be previously fabricated on one or more semiconductor wafers, and the wafer or wafers are singulated or diced to form a plurality of the integrated circuit dies 120, for example. The integrated circuit dies 120 include a substrate 122 comprising a semiconductive material and that includes circuitry, components, wiring, and other elements (not shown) fabricated within and/or thereon. The integrated circuit dies 120 are adapted to perform a predetermined function or functions, such as logic, memory, processing, other functions, or combinations thereof, as example. The integrated circuit dies 120 are typically square or rectangular in shape in a top view, not shown.

The integrated circuit dies 120 each include a first surface 128a and a second surface 128b, the second surface 128b being opposite the first surface 128a. The integrated circuit dies 120 each include a plurality of contact pads 124 formed across the first surface thereof. The plurality of contact pads 124 are disposed on a surface of the substrate 122. The contact pads 124 are electrically coupled to portions of the substrate 122. The contact pads 124 comprise a conductive material such as copper, aluminum, other metals, or alloys or multiple layers thereof, as examples. Alternatively, the contact pads 124 may comprise other materials.

The contact pads 124 are disposed within an insulating material 126 formed over the substrate 122. Portions of the top surfaces of the contact pads 124 are exposed within the insulating material 126 so that electrical connections can be made to the contact pads 124. The insulating material 126 may comprise one or more insulating material layers, such as silicon dioxide, silicon nitride, a polymer material, or other materials. The insulating material 126 comprises a passivation layer in some embodiments, for example.

A plurality of the integrated circuit dies 120 are coupled to the carrier 100. Only two integrated circuit dies 120 are shown in FIGS. 3 through 10; however, dozens, hundreds, or more integrated circuit dies 120 may be coupled to the carrier 100 and packaged simultaneously. The second surfaces 128b of the integrated circuit dies 120 are coupled to the carrier 100. The integrated circuit dies 120 are coupled to the protective film 110 which has an adhesive quality and is adapted to attach the integrated circuit dies 120 to the carrier 100. The integrated circuit dies 120 are coupled to the carrier 100, manually or using an automated machine such as a pick-and-place machine. The integrated circuit dies 120 are coupled to the carrier 100 using the protective film 110.

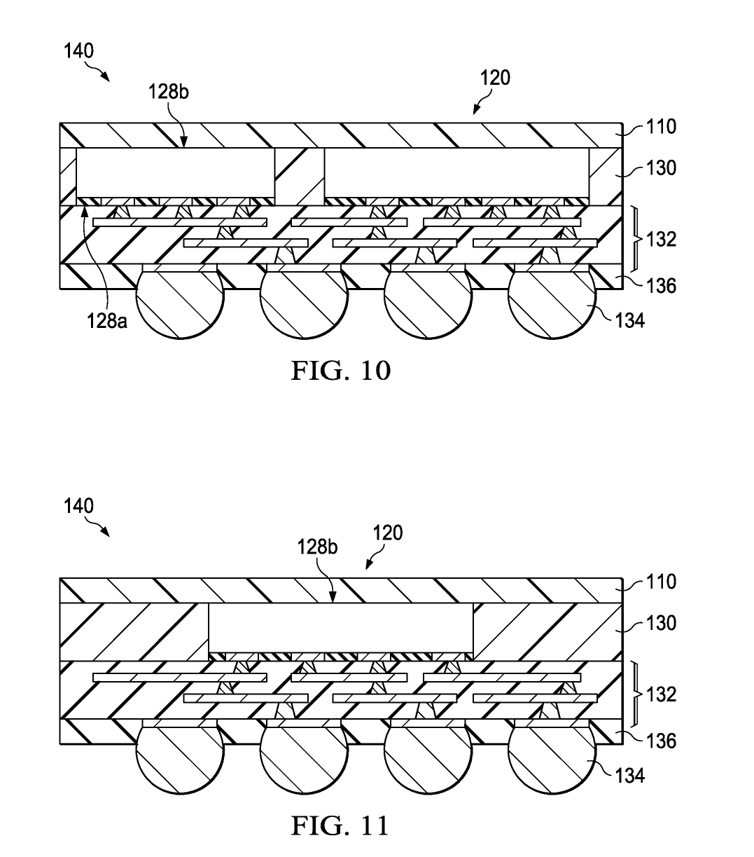

In some embodiments, the integrated circuit dies 120 are coupled to the carrier 100 and are packaged in individual packages (see FIG. 11). In other embodiments, two or more integrated circuit dies 120 can be packaged together (see FIG. 10). A plurality of integrated circuit dies 120 comprising the same or different functions may be packaged together in accordance with some embodiments, for example.

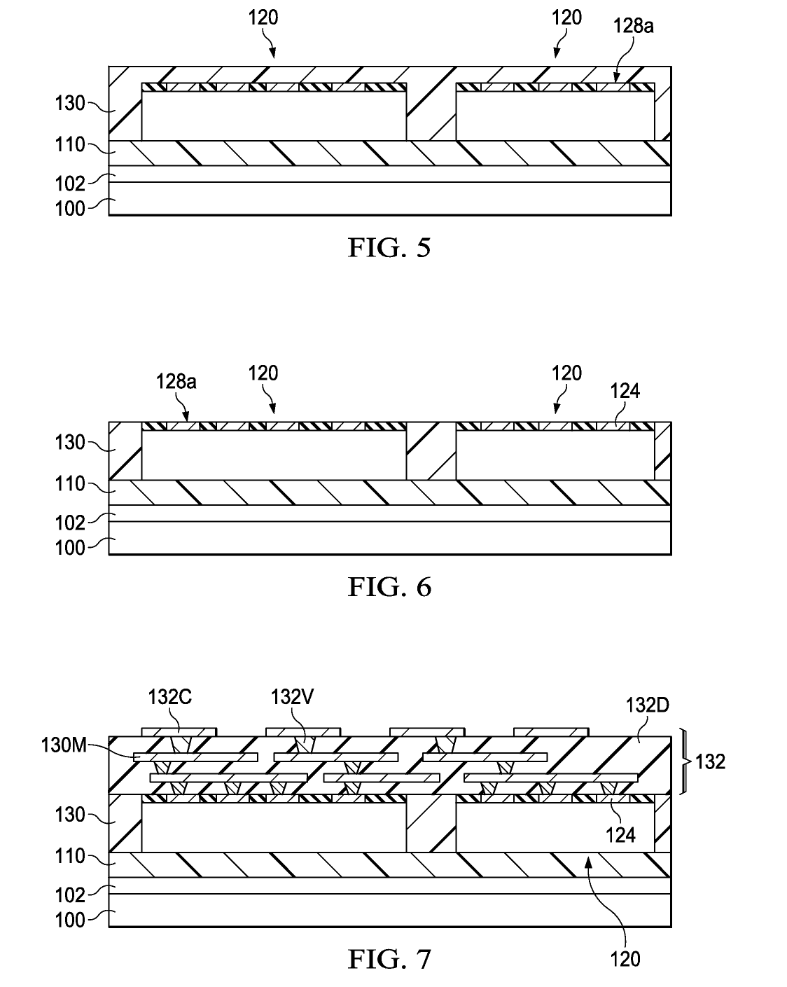

A molding material 130 is then disposed over and around the integrated circuit dies 120, as shown in FIG. 5. The molding material 130 is applied using a wafer level molding process in some embodiments, for example. The molding material 130 is formed over exposed portions of the carrier 100 (e.g., over the protective film 110 disposed on the carrier 100), over the sidewalls of the integrated circuit dies 120, and over exposed portions of the first surfaces 128a of the integrated circuit dies 120. The molding material 130 may be molded using, for example, compressive molding, transfer molding, or other methods. The molding material 130 encapsulates the integrated circuit dies 120, for example. The molding material 130 may comprise an epoxy, an organic polymer, or a polymer with or without a silica-based or glass filler added, as examples. In some embodiments, the molding material 130 comprises a liquid molding compound (LMC) that is a gel type liquid when applied. The molding material 130 may also comprise a liquid or solid when applied. Alternatively, the molding material 130 may comprise other insulating and/or encapsulating materials.

Next, the molding material 130 is cured using a curing process in some embodiments. The curing process may comprise heating the molding material 130 to a predetermined temperature for a predetermined period of time, using an anneal process or other heating process. The curing process may also comprise an ultra-violet (UV) light exposure process, an infrared (IR) energy exposure process, combinations thereof, or a combination thereof with a heating process. Alternatively, the molding material 130 may be cured using other methods. In some embodiments, a curing process is not included.

A top portion of the molding material 130 is then removed, as shown in FIG. 6. The top portion of the molding material 130 is removed using a grinding process in some embodiments, for example. The grinding process may comprise a process similar to a sanding process that is used for wood, using a rotating sander, for example. The grinding process may comprise rotating a disk lined with an appropriate material or materials for grinding the materials of the molding material 130 to a predetermined height, for example. The disk may be lined with diamond, for example. In some embodiments, a chemical-mechanical polishing (CMP) process is used to remove the top portion of the molding material 130, for example. A combination of a grinding process and a CMP process may also be used. The CMP process or grinding process may be adapted to stop when the first surfaces 128a of the integrated circuit dies 120 are reached in some embodiments, for example. The CMP process and/or grinding process comprises a front-side grinding process in some embodiments.

In some embodiments, a grinding or CMP process is not required. The molding material 130 may be applied so that the molding material 130 reaches a level that is substantially the same as the level of the first surfaces 128a of the integrated circuit dies 120 in some embodiments, for example. In some embodiments, the molding material 130 top surface may reside below the first surfaces 128a of the integrated circuit dies 120 after the application of the molding material 130, as another example, not shown.

In some embodiments, the top surface of the molding material 130 after the grinding and/or CMP process, or after the molding material 130 deposition process, is substantially coplanar with the first surfaces 128a of the integrated circuit dies 120. The molding material 130 being substantially coplanar with the first surfaces 128a advantageously facilitates in the formation of a subsequently formed interconnect structure 132, which is illustrated in FIG. 7. The top surfaces of the molding material 130 and integrated circuit dies 120 comprise a substantially planar surface for the formation of the interconnect structure 132 in some embodiments, for example.

The interconnect structure 132 comprises a post-passivation interconnect (PPI) structure or a redistribution layer (RDL) in some embodiments that is formed over the plurality of integrated circuit dies 120 and the molding material 130, for example. The interconnect structure 132 includes fan-out regions that expand a footprint of contact pads 124 on the integrated circuit dies 120 to a larger footprint for the package in some embodiments, for example. The interconnect structure 132 includes a plurality of dielectric layers 132D, and a plurality of metal lines 132M and/or a plurality of metal vias 132V formed inside the plurality of dielectric layers 132D. The plurality of metal lines 132M and the plurality of metal vias 132V provide electrical connections to contact pads 124 on the substrate 122. Three wiring levels are shown in FIGS. 7 through 10; alternatively, one, two, or four or more wiring levels may be included in the interconnect structure 132.

The dielectric layers 132D may be formed, for example, of a low dielectric constant (low-K) dielectric material, such as phosphosilicate glass (PSG), borophosphosilicate glass (BPSG), fluorinated silicate glass (FSG), SiOxCy, spin-on-glass, spin-on-polymers, silicon carbon material, compounds thereof, composites thereof, combinations thereof, or the like, by any suitable method, such as spinning, CVD, and/or plasma-enhanced CVD (PECVD). The conductive lines 132M and conductive vias 132V may comprise copper, copper alloys, other metals or alloys, or combinations or multiple layers thereof, as examples. The conductive lines 132M and conductive vias 132V may be formed using subtractive and/or damascene techniques, as examples. The conductive lines 132M and conductive vias 132V may be formed using one or more sputtering processes, photolithography processes, plating processes, and photoresist strip processes, as examples. Other methods can also be used to form the interconnect structure 132. The interconnect structure 132 includes contact pads 132C formed proximate a top surface. The contact pads 132C may comprise under-ball metallization (UBM) structures in some embodiments that are arranged in a ball grid array (BGA) or other patterns or arrangements.

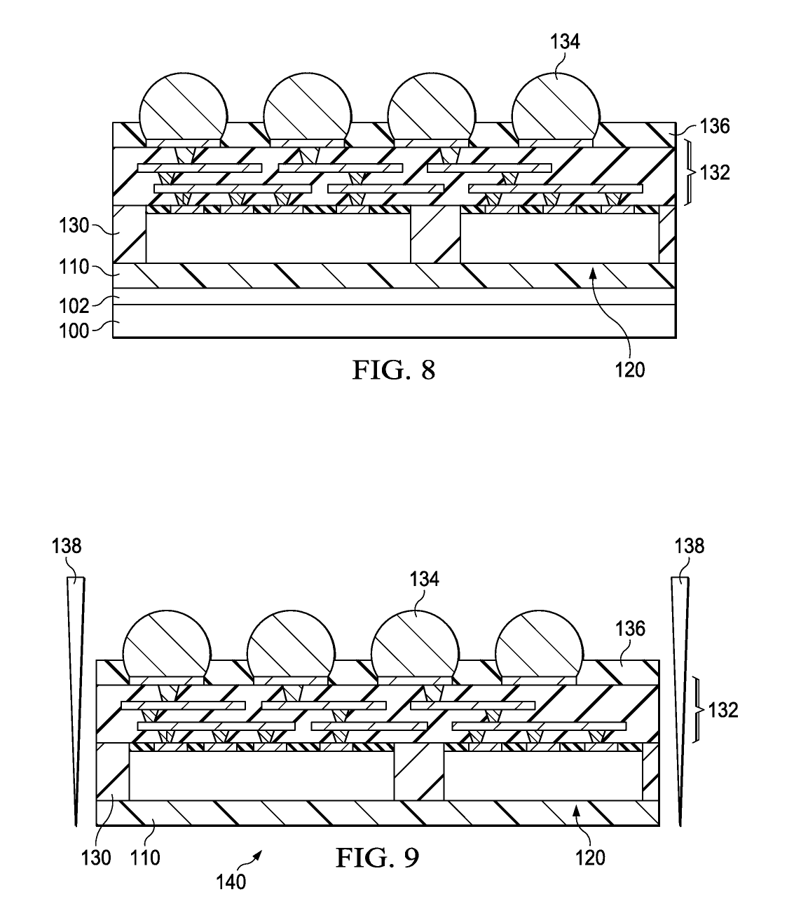

In some embodiments, a plurality of connectors 134 are coupled to the contact pads 132C of the interconnect structure 132, as shown in FIG. 8. The connectors 134 may comprise a eutectic material such as solder, for example. The eutectic material may comprise solder balls or solder paste in some embodiments that is reflowed by heating the eutectic material to a melting temperature of the eutectic material. The connectors 134 are attached using a ball mount process or other process. The eutectic material is then allowed to cool and re-solidify, forming connectors 134. The connectors 134 may include other types of electrical connectors, such as microbumps, controlled collapse chip connection (C4) bumps, or pillars, and may include conductive materials such as Cu, Sn, Ag, Pb, or the like. In some embodiments, the connectors 134 may comprise joined bumps, as another example. In some embodiments, the connectors 134 are not included on the package.

In some embodiments, an insulating material 136 is formed between the connectors 134 over the interconnect structure 132, also illustrated in FIG. 8. The insulating material 136 comprises a polymer, a molding compound, or a liquid molding compound (LMC) in some embodiments. The insulating material 136 may alternatively comprise other materials.

In some embodiments, the connectors 134 are not included in the package. In some embodiments, the insulating material 136 is not included in the package. In other embodiments, neither the connectors 134 nor the insulating material 136 are included in the packaged semiconductor devices.

The carrier 100 and film 102 are removed using a de-bonding process, and the packaged semiconductor devices 140 are singulated or diced on scribe line regions 138 to form a plurality of packaged semiconductor devices 140, as shown in FIG. 9. The molding material 130 and the interconnect structure 132 are diced along the scribe lines 138 to form the plurality of packaged semiconductor devices 140 in some embodiments, for example, as shown in FIG. 10. The protective film 110 may be placed on a dicing tape (not shown) before the dicing process in some embodiments. The dicing tape is later removed after the dicing process. The packaged semiconductor device 140 in FIG. 10 is inverted from the view shown in FIG. 9.

Two integrated circuit dies 120 are shown being packaged together in the embodiments shown in FIGS. 1 through 10, for example. Alternatively, three or more integrated circuit dies 120 can be packaged in a packaged semiconductor device 140. Portions of the interconnect structure 132 may provide horizontal electrical connections for a plurality of the integrated circuit dies 120 that are packaged together. For example, some of the conductive lines 132M and vias 132V may comprise wiring between the two or more of the integrated circuit dies 120. The molding material 130 is disposed around and between the plurality of integrated circuit dies 120. The interconnect structure 132 is disposed over the plurality of integrated circuit dies 120 and the molding material 130. The protective film 110 is coupled to each of the plurality of integrated circuit dies 120. Integrated circuit dies 120 can also be packaged singly within a packaged semiconductor device 140, as shown in FIG. 11 in a cross-sectional view.

The protective film 110 is advantageously left remaining in the packaged semiconductor devices 140 on the back side of the packaged semiconductor devices 140, as illustrated in FIGS. 10 and 11. The protective film 110 protects the second surfaces 128b of the integrated circuit dies 120. Because the protective film 110 is adhesive, the use of a die attach film (DAF) in the packaging process is advantageously not required, reducing costs and packaging time. Furthermore, because the protective film 110 provides protection for the packaged semiconductor devices 140, the use of a back side protection or molding film, heat spreader, protective lid, or protective cover for the back side of the packages are not required, which proportionally are quite expensive components in some packaging techniques and processes. Thus, including the protective film 110 in the packages results in cost and time savings.

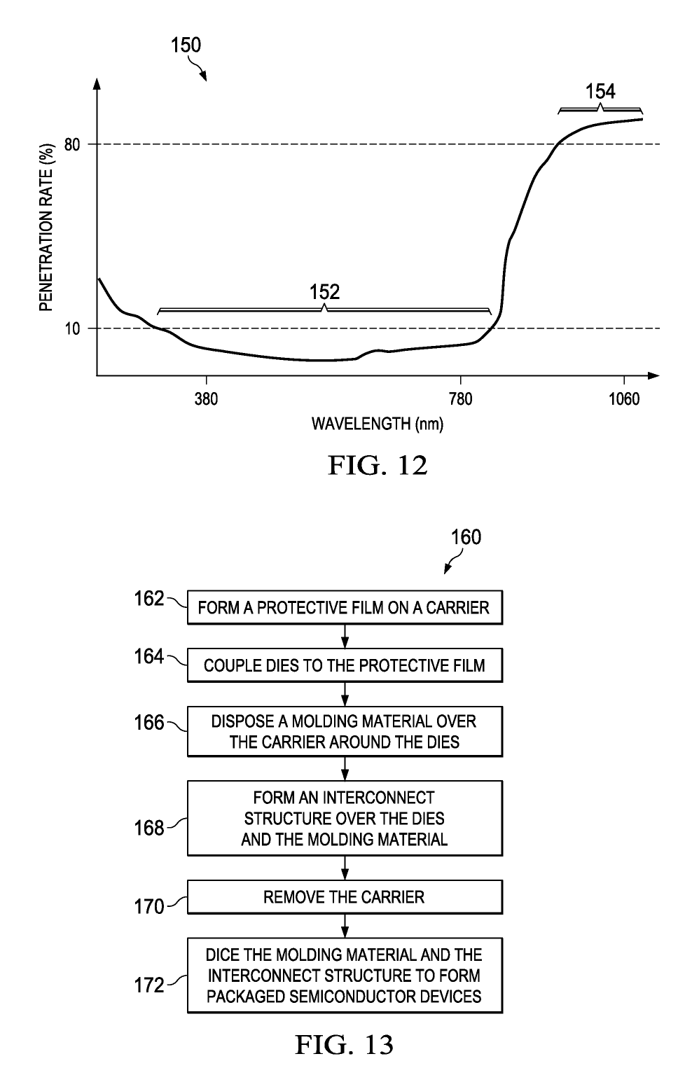

FIG. 12 is a graph 150 showing penetration rates in percentages of various wavelengths of light for the protective film 110 in accordance with some embodiments of the present disclosure. Wavelengths of light are shown along the x-axis of the graph 150 in nanometers (nm), and penetration rates at various wavelengths are shown along the y-axis of the graph 150 in percentages (%). Region 152 illustrates a region of the graph 150 wherein the opaque protective film 110 comprises a light transmittance of less than about 10% in a visible spectrum, e.g., at wavelengths of light between about 380 nm to about 780 nm, in accordance with some embodiments. Region 154 illustrates a region of the graph 150 wherein the protective film 110 comprises a light transmittance of about 80% or greater when a packaged semiconductor device 140 is exposed to a laser, such as a CO₂ laser at a wavelength of about 1,060 nm, for example, in accordance with some embodiments. Thus, at infrared (IR) wavelengths, the protective film 110 allows a greater percentage of penetration. A protective film 110 with the penetration percentage rates illustrated in FIG. 12 achieves a desired material quality and protective qualities for the protective film 110 in some applications in accordance with some embodiments, for example. Alternatively, the protective film 110 may comprise other penetration percentage rates, in other embodiments.

FIG. 13 is a flow chart 160 of a method of packaging a semiconductor device in accordance with some embodiments. In step 162, a protective film 110 is formed on a carrier 100 (see also FIG. 2). In step 164, integrated circuit dies 120 are coupled to the protective film 110 (FIGS. 3 and 4). In step 166, a molding material 130 is disposed over the carrier 100 around the integrated circuit dies 120 (FIGS. 5 and 6). In step 168, an interconnect structure 132 is formed over the integrated circuit dies 120 and the molding material 130 (FIG. 8). In step 170, the carrier 100 is removed (FIG. 9). In step 172, the molding material 130 and the interconnect structure 132 are diced to form packaged semiconductor devices 140 (FIGS. 9, 10, and 11).

Some embodiments of the present disclosure include methods of packaging semiconductor devices. Other embodiments include packaged semiconductor devices 140 that have been packaged using the novel methods described herein.

Some advantages of embodiments of the present disclosure include providing packaging methods and structures that include a novel protective film for packaged semiconductor devices. The protective film is opaque and adhesive, and provides protection for back sides of packaged semiconductor devices. The protective film can be used in place of other adhesive films used in semiconductor device packaging, and the protective film can be left remaining on the packages and used as protection. The novel protection film eliminates a need to attach other types of protection structures and films on the back sides of the packages, such as covers, plates, lids, and transparent films, which can generate ripples on the surface of packaged semiconductor devices after laser de-bonding procedures used for carriers. Thus, the protection film results in cost savings and improved packages for semiconductor devices.

The opaque protection film enhances resistance to moisture intrusion and improves thermal reliability of the packaged semiconductor devices. The protective films provide an innovative protection structure that is implementable in and particularly beneficial for wafer level packaging (WLP) or chip scale packaging (CSP) techniques and processes. De-lamination of adhesives layers and molding materials and compounds are prevented by the use of the protective films. The protection films can be integrated in WLP and CSP packaging process flows to function as a single opaque film protective structure on the back side of the integrated circuit dies and packages. Furthermore, the novel packaging methods and structures described herein are easily implementable in manufacturing and packaging process flows.

In some embodiments, a method of packaging a semiconductor device includes providing a protective film, coupling a plurality of dies to the protective film, and disposing a molding material around the plurality of dies. The protective film comprises a substantially opaque material at predetermined wavelengths of light.

In some embodiments, a method of packaging a semiconductor device includes forming a protective film on a carrier, coupling a plurality of dies to the protective film, and disposing a molding material over the carrier around the plurality of dies. The method includes forming an interconnect structure over the plurality of dies and the molding material, removing the carrier, and dicing the molding material and the interconnect structure to form a plurality of packaged semiconductor devices.

In other embodiments, a packaged semiconductor device includes an integrated circuit die, a molding material disposed around the integrated circuit die, and an interconnect structure disposed over a first surface of the integrated circuit die and the molding material. A protective film is coupled to a second surface of the integrated circuit die and the molding material, the second surface being opposite the first surface. The protective film comprises a substantially opaque material at predetermined wavelengths of light.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein.

Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of packaging a semiconductor device, the method comprising:
providing a protective film;
coupling a plurality of dies to the protective film; and
disposing a molding material around the plurality of dies, wherein the protective film comprises a substantially opaque material at predetermined wavelengths of light.

2. The method according to claim 1, wherein disposing the molding material around the plurality of dies comprises forming the molding material over the plurality of dies, and wherein the method further comprises removing a top portion of the molding material from over the plurality of dies.

3. The method according to claim 2, wherein removing the top portion of the molding material comprises a grinding process or a chemical-mechanical polishing (CMP) process.

4. The method according to claim 2, further comprising forming an interconnect structure over the plurality of dies and the molding material.

5. The method according to claim 4, further comprising coupling a plurality of connectors to the interconnect structure.

6. The method according to claim 4, wherein forming the interconnect structure comprises forming fan-out regions.

7. The method according to claim 4, wherein forming the interconnect structure comprises forming a post-passivation interconnect (PPI) structure or a redistribution layer (RDL).

8. A method of packaging a semiconductor device, the method comprising:
forming a protective film on a carrier;
coupling a plurality of dies to the protective film;
disposing a molding material over the carrier around the plurality of dies;
forming an interconnect structure over the plurality of dies and the molding material;
removing the carrier; and
dicing the molding material and the interconnect structure to form a plurality of packaged semiconductor devices.

9. The method according to claim 8, wherein forming the protective film comprises forming a substantially opaque material, and wherein the substantially opaque material is opaque at predetermined wavelengths of light.

10. The method according to claim 8, wherein forming the protective film comprises a process selected from the group consisting essentially of a spin-on process, chemical vapor deposition (CVD), physical vapor deposition (PVD), sputtering, a lithography process, a taping process, a lamination process, and combinations thereof.

11. The method according to claim 8, wherein the protective film is disposed on a back side of the plurality of packaged semiconductor devices.

12. The method according to claim 8, wherein the method comprises a wafer level packaging (WLP) technique or a chip scale packaging (CSP) technique.

13. A packaged semiconductor device, comprising:
an integrated circuit die;
a molding material disposed around the integrated circuit die;
an interconnect structure disposed over a first surface of the integrated circuit die and the molding material; and
a protective film coupled to a second surface of the integrated circuit die and the molding material, the second surface being opposite the first surface, wherein the protective film comprises a substantially opaque material at predetermined wavelengths of light.

14. The packaged semiconductor device according to claim 13, wherein the protective film further comprises an adhesive quality.

15. The packaged semiconductor device according to claim 13, wherein the protective film comprises a light transmittance of less than about 10% in a visible spectrum.

16. The packaged semiconductor device according to claim 13, wherein the protective film comprises a light transmittance of about 80% or greater when exposed to a laser.

17. The packaged semiconductor device according to claim 13, wherein the protective film comprises a material selected from the group consisting essentially of epoxy, phenol, silica, organic dye, and combinations thereof.

18. The packaged semiconductor device according to claim 13, wherein the protective film comprises a thickness of about 10 μm to about 50 μm.

19. The packaged semiconductor device according to claim 13, further comprising a plurality of connectors coupled to the interconnect structure, and an insulating material disposed between portions of the plurality of connectors.

20. The packaged semiconductor device according to claim 13, further comprising a plurality of the integrated circuit dies, wherein the molding material is disposed around and between the plurality of integrated circuit dies, wherein the interconnect structure is disposed over the plurality of integrated circuit dies and the molding material, and wherein the protective film is coupled to each of the plurality of integrated circuit dies.
